(19) United States
(12) Patent Application Publication
(10) Pub. No.: US 2009/0057746 A1
(43) Pub. Date: Mar. 5, 2009

(54) SEMICONDUCTOR DEVICE

(75) Inventors: Nobuyuki Sugll, Tokyo (JP); Ryuta Tsuchiya, Tokyo (JP); Shinichiro Kimura, Kunitachi (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/187,504

(22) Filed: Aug. 7, 2008

(30) Foreign Application Priority Data
Sep. 5, 2007 (JP) JP2007-229811

(51) Int. Cl. H01L 29/788; H01L 29/06

(52) U.S. Cl. 257/315; 257/348; 257/E29.3; 257/E29.137

(57) ABSTRACT

A semiconductor device having a passive element whose characteristic is adjustable even after manufacture by applying back bias voltage is provided. Formed on a main surface of a SOI substrate comprising a supporting substrate, a BOX layer, and an SOI layer is a MOS varactor comprising a gate dielectric formed on a surface of the SOI layer, a gate electrode formed on the gate dielectric, and a n⁺ type semiconductor region formed in the SOI layer located on both sides of the gate electrode. The MOS varactor, is configured so that capacitance formed by the SOI layer, gate dielectric, and gate electrode is varied by applying bias voltage to the supporting substrate (p type well) under the gate electrode.

### CROSS-REFERENCE TO RELATED APPLICATION

The present application claims priority from Japanese patent application No. JP 2007-229811 filed on Sep. 5, 2007, the content of which is hereby incorporated by reference into this application.

### TECHNICAL FIELD OF THE INVENTION

The present invention relates to a semiconductor device, particularly, the present invention relates to a technique that is effectively applied to a semiconductor device comprising a varactor (variable-capacitance device) or a resistor used in a wireless information communication apparatus and the like.

### BACKGROUND OF THE INVENTION

A silicon field effect semiconductor device for logic element has continuously improved its performance such as integration and operating speed and reduced power consumption per device by miniaturizing strenuously the semiconductor device. However, since generation in which a processing dimension of the device is less than 50 nm comes, it has become difficult to achieve both of improvement of performance and reduction of power consumption.

Such problems have been caused by, for example, limit in an operating current due to velocity saturation of carriers, and an increase in a leakage current from a gate oxide film, and the like. As a representative means to solve those problems, a high-k gate dielectric or a high-mobility channel such as strained silicon has been developed. The former mainly reduces power consumption in a standby state of an electric circuit by suppressing a tunnel leakage current flowing through an ultrathin gate dielectric. The latter improves operating speed by increasing an output current of the device with the same dimension, or reduces the power consumption in a given state of the operating speed.

In addition to these problems, an increase of variation among the devices becomes more serious as a new problem associated with progress of miniaturization of the devices. As the variation among the devices becomes larger, it is difficult to reduce voltage of a power source along with the miniaturization of the devices because voltage margin necessary to make all circuits operate normally needs to be ensured.

This makes it difficult to reduce power consumption per device, and increases power consumption of a highly integrated, miniaturized semiconductor chip. Furthermore, if variation among the devices is large, some devices with poor power consumption performance in the devices significantly increase power consumption of the chip as a whole. Therefore, although it has been possible thus far to increase size and functions of the circuits without changing power consumption of the chips with the same area by miniaturization, such an increase is now difficult.

As a technique capable of suppressing variation among the devices to dramatically improve performance of the semiconductor chip, a SOI (Silicon On Insulator) technique as shown in Patent Document 1 (Japanese Patent Application Laid-Open Publication No. 2005-251776) has been disclosed. This technique, unlike a conventional SOI technique, makes it possible to change the threshold voltage of the device by forming a fully-depleted Silicon-On-Insulator (FDSOI) device using a SOI substrate having an ultrathin SOI layer and an ultrathin buried oxide (BOX) layer and by applying bias voltage from a back surface of the BOX layer.

If the FDSOI technique mentioned above is used, for example, it is possible to adjust bias voltage of the chip, in which variation of the power consumption is large, after the device is manufactured and to return such power consumption to an optimal level. Therefore, yield of the chip can be improved. Furthermore, when an interior of the chip is divided into a plurality of regions to form such a circuit structure as to automatically adjust the bias voltage for each region independently, characteristics of all transistors in the chip can be better adjusted, so that the power consumption of the chip can be further reduced.

Currently, in semiconductor integrated circuit chips, it is demanded to be equipped with high-performance logic circuits and simultaneously integrate analog circuits and high-frequency circuits on the same chip. In order to manufacture such circuits, passive elements such as a capacitance device and a resistor must be integrated on the chip in addition to a transistor for logic circuit. Also in the semiconductor device which uses the FDSOI technique mentioned above and is a subject of the present invention, integration of the passive elements is required.

Among the passive elements, a varactor (variable-capacitance device) conventionally includes a diode type which uses pn junction capacitance, and a MOS capacitance type which uses a MOS transistor structure. The latter is described in Patent Documents 2 to 4 as mentioned blow.

Patent Document 2 (Japanese Patent Application Laid-Open Publication No. 2005-072125) disclose a MOS varactor structure of an SOI device, wherein voltage applied to a substrate is fixed to the same voltage as drain voltage, and a high impurity concentration is introduced into a region of a back surface of the BOX layer. Patent Document 3 (Japanese Patent Application Laid-Open Publication No. 2004-140148) relates to SOI type MOS capacitance, but discloses a technique for using no substrate potential. Patent Document 4 (Japanese Patent Application Laid-Open Publication No. 2003-318417) discloses, in a structure in which back bias is applied to bulk type MOS capacitance, such a characteristic that a mode of controlling pinch-off generating voltage of a MOS transistor by back bias is used; and a capacitance change due to the voltage applied thereto is steep.

As the resistor among the passive elements, conventionally, well resistance formed by diffusing impurity in a silicon substrate is used. The well resistance is described in Patent Documents 5 to 7 as mentioned below. In Patent Document 5 (Japanese Patent Application Laid-Open Publication No. 2003-174094), the same potential is applied also to a silicon layer in a back surface of a BOX layer when the SOI layer is operated as bleeder resistance. Patent Document 6 (Japanese Patent Application Laid-Open Publication No. 2001-144254) discloses a method of controlling channel resistance of an SOI layer by gate voltage. In Patent Document 7 (Japanese Patent Application Laid-Open Publication No. 2006-049711), the same potential is applied also to a gate electrode contacting with an SOI layer when the SOI layer is operated as bleeder resistance.

### SUMMARY OF THE INVENTION

When the passive elements are intended to be further integrated on the chip equipped with the above-mentioned FDSOI devices, since a substrate different from a conventional bulk device is used, a conventional process cannot be used for such integration of the passive elements.

That is, since an SOI substrate used in the FDSOI device usually has a thin SOI layer with a thickness of approximately 20 nm or less, it is difficult to manufacture the passive elements on this layer using the conventional process. For this reason, a device structure which can function as a passive element without causing any problems even when a thin-film SOI substrate for FDSOI device is used, and a manufacturing process for such a device structure become necessary.

In the FDSOI device which has a thin BOX layer disclosed in Patent Document 1 and is a subject of the present invention, the thin SOI layer and the BOX layer are partially removed to expose the underneath bulk silicon substrate, whereby the bulk silicon device can be manufactured on the exposed bulk silicon substrate. Accordingly, manufacturing of passive elements having the same performance as that of the passive elements manufactured on the bulk silicon substrate is required to add the above removing process, but the addition of the removing process can be performed relatively easily.

However, in the conventional bulk type passive elements, device characteristics obtained depending on pre-designed device size or impurity concentration are fixed. From the viewpoint of easiness of analog circuit design, the passive elements which can be controlled over a wider range, especially, the elements whose characteristics are adjustable after the manufacturing are desirable.

For example, in the diode type one among the varactors as described above, its capacitance is variable by changing the bias voltage applied to the pn junction. However, since parasitic capacitance passing through the substrate is large and the parasitic resistance is difficult to reduce, it is structurally difficult to improve a Q value representing quality of the passive element. Meanwhile, in the latter MOS type varactor, capacitance formed between a gate and a channel of the MOS transistor is used. However, there is the problem that capacity controllability degenerates due to a magnitude of alternating-current amplitude.

Moreover, since the well resistance described above is formed on the silicon substrate, the parasitic capacitance is increased and the Q value cannot become lower. Additionally, since control of the resistance value is required to be performed by the impurity concentration and size of the resistor, i.e., by a ratio of its length to its width, the resistance value cannot be adjusted after the manufacturing.

There is a method in which the resistor is used as a part of a wiring layer besides the well resistance, for example, used in forming a polycrystalline silicon layer or metal layer. In this case, there are advantages of being capable of making the parasite capacitance lower and the Q value higher for forming the resistor in the wiring layer, and further of adjusting its resistance value by a method such as laser trimming or fuse after the manufacturing. However, this adjustment has to be made per individual chip, and a method of automatic adjustment by a circuit mounted on the chip in advance is not taken, whereby manufacturing cost of the chip is inevitably increased.

The FDSOI device, which is the subject of the present invention, has a remarkable advantage of being capable of freely adjusting its device characteristic by the back bias control via the thin BOX layer. As mentioned above, it is also possible to manufacture the conventional type of passive elements on the bulk region. However, by using positively the characteristics of the back bias control, the characteristics of the passive elements can be arbitrarily controlled externally after the manufacturing, whereby the passive elements that are easily designed and have many merits in the manufacturing can be provided.

Thus, the present invention is produced for a high-quality passive element whose characteristics can be arbitrarily controlled based on a structure of a FDSOI device, and detailed contents thereof will be described below.

An object of the present invention is to provide a semiconductor device comprising a passive element whose characteristics can be adjusted by applying back bias voltage thereto even after manufacture.

The above and other objects and novel features of the present invention will be apparent from descriptions of the present specification and the accompanying drawings.

Outline of representative ones of the inventions disclosed in the present application will be described as follows.

First, an operation of a fully-depleted silicon-on-insulator device (hereinafter, “FDSOI device”), which is a subject of the present invention, will be described.

As a material for a substrate, an SOI substrate having a thin BOX layer, for example, having a thickness of approximately 10 nm to 20 nm, is used. A SOI type MOS transistor comprises a source, a drain, and a gate electrode similarly to those of a conventional bulk MOS transistor, and further a substrate (body) electrode is formed therein. In a case of a Bulk MOS transistor, there is formed a substrate electrode in which a diffusion layer, which has the same conduction type as that of a well and has a high impurity concentration, is provided at a portion contacting with a silicon substrate. However, in a case of an SOI type MOS transistor, a substrate electrode is formed by removing a SOI layer and a BOX layer to provide, to a supporting substrate (silicon substrate) on a back surface of the exposed BOX layer, the same diffusion layer as that of the bulk MOS transistor. Incidentally, the well is provided in the supporting substrate on the back surface of the BOX layer similarly to the diffusion layer. Since those structures have been detailed in Patent Document 1, their description will be omitted here.

As for the SOI type MOS transistor mentioned above, threshold voltage of the MOS transistor can be arbitrarily controlled by back bias voltage applied to the substrate electrode. Back bias control is possible also in the bulk MOS transistor, but there is a big difference between a SOI type MOS transistor and the bulk MOS transistor in that back bias can be applied to a positive direction in the SOI type transistor. Incidentally, in this specification, bias in the positive direction means the relationship that a potential is higher at the substrate than at the source in a case of a NMOS transistor while a potential is reverse thereto in a case of a PMOS transistor.

When the back bias is applied in the positive direction in a bulk device, if a potential difference between the source and the substrate electrode exceeds a built-in potential of a pn junction (approximately 0.6 V), the pn junction becomes a forward direction. Therefore, a leakage current from the substrate electrode to the source is generated, whereby the back bias cannot be applied. In contrast, in a FDSOI device, since the substrate electrode and a portion of the well is fully isolated by a BOX dielectric, any bias voltage can be applied as long as it does not exceed BOX dielectric strength voltage. Incidentally, even when the BOX layer is thin to a degree of a thickness of 10 nm, approximately 10 V can be ensured as the BOX dielectric strength voltage, so that no problem is caused especially.

Thus, the operation of the device obtained when the back bias is applied in the positive direction has the feature that a region on the back surface of the BOX layer is depleted. For this reason, parasitic capacitance penetrating from the SOI layer to the supporting substrate is remarkably reduced. Therefore, when the passive elements such as MOS varactors are operated and an alternating current flows therein in a mode of depleting a supporting substrate side, it is possible to increase the Q value and reduce loss.

Incidentally, in Patent Document 2 described above, the high impurity concentration in the supporting substrate side prevents depletion from occurring within a range of the practical back bias voltage. Therefore, parasitic capacitance from a channel portion of the SOI layer to the supporting substrate increases, and the operating characteristics of the varactors cannot be variable. In Patent Document 3, the operating characteristics of the structure disclosed are also fixed. Since the structure disclosed in Patent Document 4 is a bulk type, the back bias is applied in a negative direction, in which threshold voltage is higher, and reduction of the parasitic capacitance is difficult. Furthermore, since capacitance is variable by the pinch-off characteristic, the capacitance variability becomes steep and is difficult to control.

Next, an operation of an SOI type MOS varactor will be described below. Like the SOI type MOS transistor, the SOI type MOS varactor may be configured as either an N type or P type, and may be configured as either an inversion type or accumulation type. Table 1 shows impurity conductivity types of a source, a drain, a substrate (abbreviated as “S”, “D”, and “B” in turn) and a channel. Also, FIG. 1 shows capacitance characteristics of respective configurations mentioned above.

TABLE 1

| | | P | | |
|---|---|---|---|---|
| | N Inversion | Accumulation | N Accumulation | P Inversion |
| S, D | N | P | N | P |
| Channel | P | P | N | N |
| B | P or N | P or N | N or P | N or P |

As shown in FIG. 1, points where capacitance varies by back bias voltage Vbg are shifted continuously. Therefore, even when the varactor is applied to various circuits different in alternating current amplitude, optimal variable capacitance profile to the various circuits can be taken by adjusting the back bias voltage Vbg.

Further, in a manufacturing process of the MOS transistors, their characteristics fluctuate by various manufacturing variations thereof. However, in the SOI type MOS varactors, even if their manufacturing variations occur, their characteristics can be maintained constant by adjusting setting points of the back bias voltage after the manufacturing.

The setting points of the back bias voltage mentioned above can be adjusted fully automatically. That is, a circuit for monitoring an operating characteristic such as frequency can be provided in a circuit block that corrects the passive element, and a feedback type bias voltage generation circuit may be provided so as to automatically adjust the characteristic to a desirable value according to values obtained by the monitoring. Such a circuit causes no problem regarding its size being small, and has generally an increase of an area slightly more than that occupied by the entire analog circuit. When the analog circuit especially has a plurality of frequency bands or modulation modes, the bias voltage may be automatically shifted according to each frequency band or modulation mode and can be caused to correspond to a multiband, and a multimode, etc. in the same circuit. Of course, the bias can be adjusted externally by using fuses and the like after the manufacturing.

Next, an operation of an SOI type resistance device will be described. It is identical to a case of ordinary type well resistance that, by introducing appropriate impurity into the SOI layer, conductivity type and resistivity is adjusted; a dimension ratio (ratio of length L and width W of the resistance) is adjusted; a diffusion layer having the same conductivity type and high-concentration impurity is provided at an electrode portion; and the like.

A difference between the resistor of the present invention and the conventional resistor is a SOI structure in which appropriate impurity is introduced into the supporting substrate on the back surface of the thin BOX layer; and the variable back bias is applied to an impurity introduced portion. Especially, as described above, when the back bias is applied in the positive direction, since the supporting substrate is depleted, the parasitic capacitance is significantly reduced, which results in the Q value being improved. In the ordinary MOS transistor, a gate electrode is located on a surface side of the SOI layer. However, in the device of the present invention, a gate electrode may be or may not be located.

First, a case where the gate electrode is located, the above diffusion layer can be formed by a self-aligned process similar to a case of forming the diffusion layer in the MOS transistor. By connecting the gate electrode to ground, Vdd, or any voltage source, a resistance value can be also arbitrarily varied. However, in this case, since the gate electrode is grounded for ac signal as viewed from the SOI layer, gate capacitance is regarded as large parasitic capacitance.

In order to reduce the parasitic capacitance, thickness of a gate oxide film should be increased. However, a gate dielectric on the ultrathin SOI layer is usually provided for a logic core MOS transistor, and it is necessary to oxide the SOI layer to make the gate dielectric. Therefore, the film thickness cannot be easily increased, which results in making the manufacturing process more complicated. One option to solve this problem in a simple manner is to float a gate electrode. By doing so, the gate electrode viewed from the SOI layer is not regarded as parasitic capacitance.

The resistance value is adjusted not by a front gate but by the back bias voltage. In this case, when the back bias voltage is applied in the positive direction, the resistance value of the channel in the SOI layer is changed in a direction of becoming lower and the supporting substrate is depleted. Therefore, the Q value can be made higher. In this case, since the resistivity of the channel is changed in a direction of becoming lower, an area occupied by the device can be reduced. The resistance value can be fine adjusted by adjustment of the back bias voltage even after the manufacturing. Incidentally, when the device is considered as a normally-on type MOS transistor controlled by the back gate, a change in the resistance of the channel in the SOI layer can be easily understood.

Another option is a method of providing no front gate. In this case, a self-aligned process cannot be used in forming the diffusion layer. However, in a manufacturing process of a CMOS device, a mask is used to separately form diffusion layers of NMOS and PMOS. At this time, if a region of the resistor except for the diffusion layer is covered by a mask, high-concentration impurity for forming the diffusion layer is not formed, so that the CMOS device can be manufactured, only by a change in design of the mask, in the same number of processes as the self-aligned process mentioned above. Also in this method, a method of applying the above-mentioned back bias can be performed similarly to the above description.

As mentioned above, in a case of the resistor whose potential is not fixed by the front gate, a potential of a surface of the SOI layer may fluctuate by an induction field from the outside to change the resistance value. In order to prevent this, for example, a first wiring layer may be designed to cover the resistor to give a fixed potential.

In Patent Documents 5 and 7 described above, the same effect is obtained by fixing the potential of the front gate or of the back surface of the SOI layer. In this case, however, the electrode for fixing the potential is adjacent to a path of an alternating current, so that there is a worry that its parasitic capacity may be increased and the Q value may be decreased. In the present invention, the same effects may be obtained by the followings: the parasitic capacitance is reduced by depletion of the back surface of the SOI layer and elimination or non-grounding of the front gate; and a shielding layer is provided on a location which is far from the resistor and is higher than the first wiring layer having no great influence on the parasitic capacitance.

It is desirable that a substrate to be used has the following specification. First, in order to form the SOI type MOS transistor for logic circuits simultaneously, an SOI layer having a thickness of approximately 200 nm or less is preferably used. In a case of the SOI type MOS transistor, in order that a film has finally an optimal thickness value according to necessary gate length, the substrate to be used is adjusted by, for example, a method of sacrificially oxidizing the SOI layer. It is desirable to have roughly a film thickness of half or less, or approximately one-third or less of the gate length.

Incidentally, it is not necessary to have this film thickness over the entire region of the LSI. For example, a portion of the varactor or resistor has no restriction on the above film thickness, and may have the film thickness which is set appropriately according to the Q value, resistance value, or capacitance value, etc. that is required. However, needless to say, since forming the film thickness different in each region makes a manufacturing process more complicated, it is desirable to make the film thickness uniform. The concentration of impurity in the SOI layer is low and is order of approximately 10¹⁵/cm³ in general, and is adjusted by ion implantation if necessary.

Next, it is desirable that the thickness of the BOX layer is in a range from approximately 5 nm or more to 50 nm or less in order to facilitate control by the back bias.

Although the impurity concentration of the supporting substrate is arbitrary, it is ordinarily set lower similarly to the above-mentioned SOI layer and, if necessary, an appropriate amount of impurity may be introduced into the back surface of the BOX layer by an ion-implantation method etc. Especially, when the back bias of the back surface of the BOX layer is changed to positive bias and is depleted, it is preferable to make an impurity concentration of the depleted back bias lower (roughly approximately 10¹⁹/cm³ or less). It is desirable in Table 1 that a supporting substrate 1 is an N type in the case of N inversion and N accumulation while the supporting substrate 1 is a P type in the case of P inversion and P accumulation. Meanwhile, it is preferable that, in a region for forming a MOS transistor for logic circuit, its impurity concentration is within a range from approximately 10¹⁷/cm³ or more to approximately 10¹⁹/cm³ or less in order to ensure short channel characteristics. When a high-frequency circuit is mounted simultaneously, the impurity concentration of the supporting substrate is set further lower, i.e., at roughly approximately 1000 Ωcm in terms of resistivity of silicon, so that when a so-called high-resistance silicon substrate is used as a supporting substrate, loss of high-frequency signals is preferably reduced.

As to a plane orientation of the substrate, similarly to that of an ordinary silicon device, an SOI substrate whose surface is a face (100) is usually used. However, in order to improve performance of a PMOS transistor, a surface of the PMOS transistor may be used as a face (110), or a hybrid plane-orientation substrate whose surface is mixed by a face (100) and the face (110) may be used. The passive element, which is a subject of the present invention, has no restriction on a crystal plane orientation, so that an impurity concentration, film thickness, a dimension ratio of the device, and the like can be appropriately adjusted to obtain a capacitance characteristic or resistance characteristic that is suitable according to the plane orientation set by other requirements.

Further, a direction of forming each device, that is, a direction of a current flowing in the device and an in-plane crystal orientation of crystal (SOI layer) that forms the device, are set to a direction appropriately optimal for the above crystal plane orientation. However, also as regards this, similarly to the above plane orientation, no restriction on this passive element is made, and a parameter such as an impurity concentration as mentioned above may be appropriately adjusted to obtain a desirable characteristic.

Further, for the purpose of improving performance of a short channel logic element, there is frequently used a technique for applying strain to a silicon crystal or SOI layer. However, this technique also imposes no restriction on the operation of the passive element of the present invention. That is, the characteristic of the passive element may be set by appropriately adjusting the parameter in the same manner as mentioned above according to requirement for a characteristic of the MOS transistor for logic circuit that is formed simultaneously.

Effects obtained by representative ones of the inventions disclosed by the present application will be described as follows.

According to the present invention, a passive element, such as a varactor or resistor, whose characteristic is freely adjustable, especially, automatically adjustable even after manufacturing, can be manufactured by back bias in a process common to a process of manufacturing an SOI type MOS transistor.

Also, by applying back bias voltage in a positive direction, a passive element with small parasitic capacitance and a high Q value can be provided.

Accordingly, since a high-quality analog circuit and a high-frequency circuit are easily mounted simultaneously on a semiconductor substrate on which a high-performance and less power-consumption logic circuit is formed, an information-communication terminal with high performance and less power consumption can be provided.

### BRIEF DESCRIPTION OF THE DRAWINGS

FIG. 1 is a graph that illustrates a capacitance characteristic of a varactor according to the present invention;

FIG. 2 is a sectional view of a main part of an SOI substrate showing a manufacturing method of a semiconductor device according to the present invention;

FIG. 3 is a sectional view of the main part of the SOI substrate showing a manufacturing method subsequent to FIG. 2;

FIG. 4 is a sectional view of the main part of the SOI substrate showing a manufacturing method subsequent to FIG. 3;

FIG. 5 is a sectional view of the main part of the SOI substrate showing a manufacturing method subsequent to FIG. 4;

FIG. 6 is a sectional view of the main part of the SOI substrate showing a manufacturing method subsequent to FIG. 5;

FIG. 7 is a sectional view of the main part of the SOI substrate showing a manufacturing method subsequent to FIG. 6;

FIG. 8 is a sectional view of the main part of the SOI substrate showing a manufacturing method subsequent to FIG. 7;

FIG. 9 is a sectional view of the main part of the SOI substrate showing a manufacturing method subsequent to FIG. 8;

FIG. 10 is a sectional view of the main part of the SOI substrate showing a manufacturing method subsequent to FIG. 9;

FIG. 11 is a sectional view of the main part of the SOI substrate showing a manufacturing method subsequent to FIG. 10;

FIG. 12 is a graph that illustrates a capacitance characteristic of a MOS varactor according to the present invention;

FIG. 13 is a graph that illustrates the capacitance characteristic of the MOS varactor according to the present invention;

FIG. 14 is a graph that illustrates the capacitance characteristic of the MOS varactor according to the present invention;

FIG. 15 is a graph that illustrates the capacitance characteristic of the MOS varactor according to the present invention;

FIG. 16 is a diagram of a voltage controlled oscillation circuit in which the MOS varactor according to the present invention is a differential type;

FIG. 17 is a plane layout view that is preferable in a case where the MOS varactor according to the present invention is a differential type;

FIG. 18 is a sectional view taken along line A-A of the FIG. 17;

FIG. 19 is a graph that illustrates a characteristic of a resistor according to the present invention; and

FIG. 20 is a circuit diagram for explaining a method of controlling operating characteristics of a circuit which comprises the MOS varactor and the resistor according to the present invention.

### DESCRIPTION OF PREFERRED EMBODIMENTS

The following embodiments will be described by dividing them into a plurality of sections or sub-embodiments if necessary for convenience. However, except for a case of be specified especially, those sections or sub-embodiments are not independent from one another, and one of them has a relationship with modification, detail, or supplement of a part or entirety of the other of them.

Also, in the following embodiments, when the number of elements (including the number of pieces, values, amounts, and ranges, etc.) is mentioned except for a case of being specified especially or case of being limited to a clearly specific number in principle, the embodiments are not limited to the specific number and may be over or below the specific number.

Further, in the following embodiments, needless to say, their components (including elements, and steps, and the like) are not necessarily indispensable expect for a case of being specified especially or a case of being considered to be evidently indispensable in principle. Similarly, in the embodiments as described below, when a shape and a positional relation of the components and the like are mentioned except for a case of being specified especially or a case of being considered not to be clear in principle, they include ones substantially approximate or similar to the shape etc. This is applicable also to the above values and ranges.

Hereinafter, the embodiments of the present invention will be detailed with reference to the accompanying drawings. Incidentally, throughout all Figures for explaining the embodiments, the same components are denoted in principle by the same reference numerals, and repetitive description thereof will be omitted. Also, since the drawings are given for the illustrative purpose only, a relation between thickness and a plane dimension and a ratio of thickness of each layer should be determined according to the following description.

Further, the embodiments described below are presented only for the purpose of illustrating devices or methods for embodying a technical concept of the present invention. The technical concept of the present invention is not limited to materials, shapes, structures, arrangements, and operating voltages of components set forth in the embodiments.

### Embodiment 1

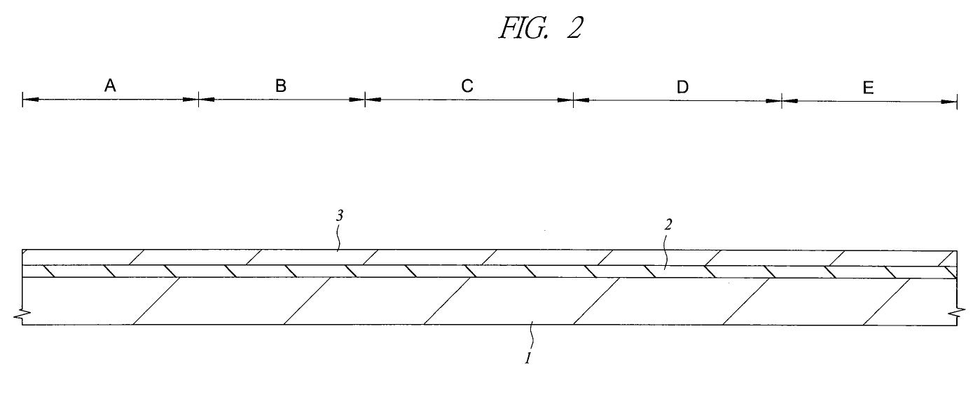

A manufacturing method for a semiconductor device according to the present invention will be described in order of steps with reference to FIGS. 2 to 11. Regions shown by the reference numerals “A” to “D” in each Figure are FDSOI device forming regions. Among them, a region (A) represents a NMOS transistor forming region; a region (B) a PMOS transistor forming region; a region (C) a MOS varactor forming region; and a region (D) a resistor forming region. Also, a region (E) represents a bulk device forming region, but, for simplifying its explanation, only a bulk NMOS transistor will be illustrated and described and illustration and description of other devices will be omitted.

First, as shown in FIG. 2, an SOI substrate comprising a supporting substrate 1, a BOX layer 2, and an SOI layer 3 is provided. The supporting substrate 1 is formed of a p type monocrystalline silicon having a plane orientation (100) and a resistivity of approximately 5 Ωcm. The SOI layer 3 is formed of p type monocrystalline silicon having a plane orientation (100), a crystal orientation <110> parallel to an orientation flat or notch, and a thickness of 30 nm. The BOX layer 2 is formed of an oxide silicon film having a thickness of 10 nm.

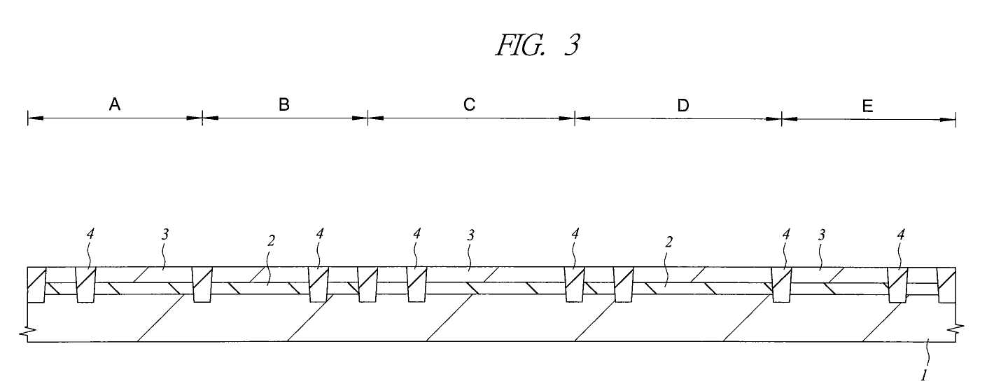

Next, as shown in FIG. 3, a device isolation trench 4, which extends from a surface of the SOI layer 3 to the supporting substrate 1 and has a depth of approximately 300 nm, is formed using a well-known STI (Shallow Trench Isolation) technique.

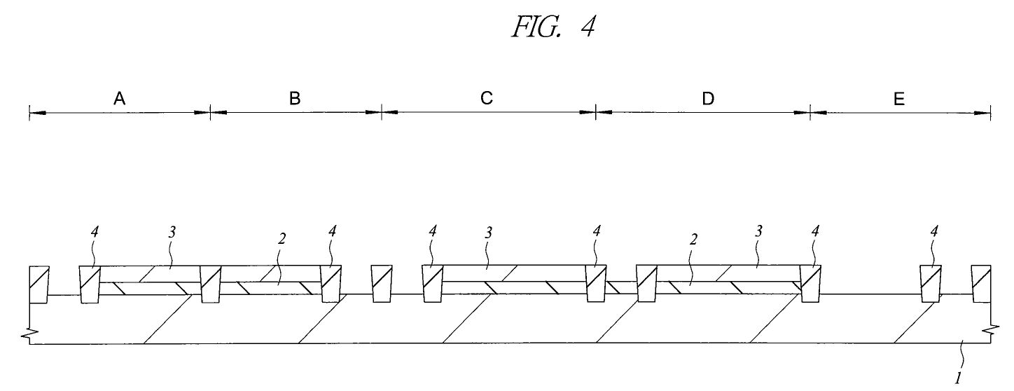

Next, as shown in FIG. 4, the surface of the supporting substrate 1 is exposed by dry-etching and wet-etching the SOI layer 3 and the BOX layer 2 in the region (E). At this time, also in the FDSOI device forming region, the SOI layer 3 and the BOX layer 2 in a region contacting with a well are removed to expose the surface of the supporting substrate 1. Since the exposed surface of the supporting substrate 1 is an interface for bonding the BOX layer 2 and the supporting substrate 1 to each other, sacrificial oxidation is performed thereon, if necessary, to remove a part of a surface layer of the interface.

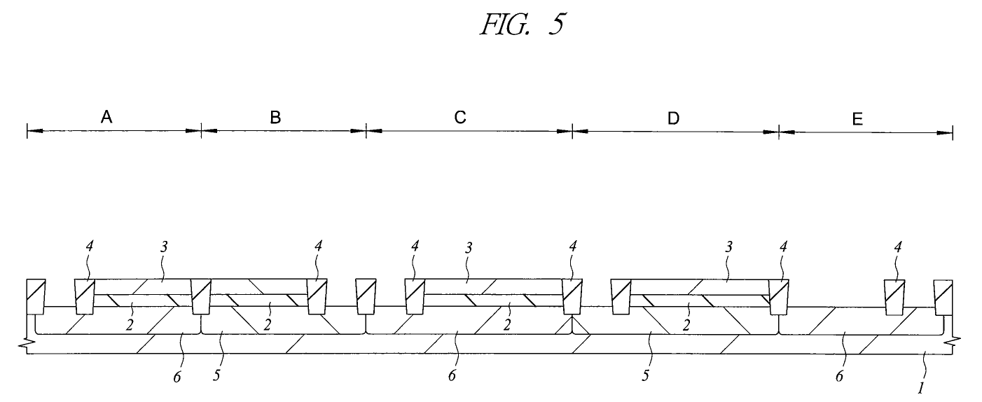

Next, as shown in FIG. 5, an n type well 5 and a p type well 6 are formed on the supporting substrate 1 by performing ion implantation of impurity and a rapid heat treatment for activating the impurity. An impurity concentration of the p type well 6 in the region (A) and that of the n type well 5 in the region (B) are adjusted to be approximately 10¹⁸/cm³. Also, the impurity concentration of the p type well 6 in the region (C) and the n type well 5 in the region (D) is adjusted to be approximately 10¹⁷/cm³. The impurity concentration of the p type well 6 in the region (E) is adjusted to an impurity concentration optimal to a characteristic of a device to be formed in this region.

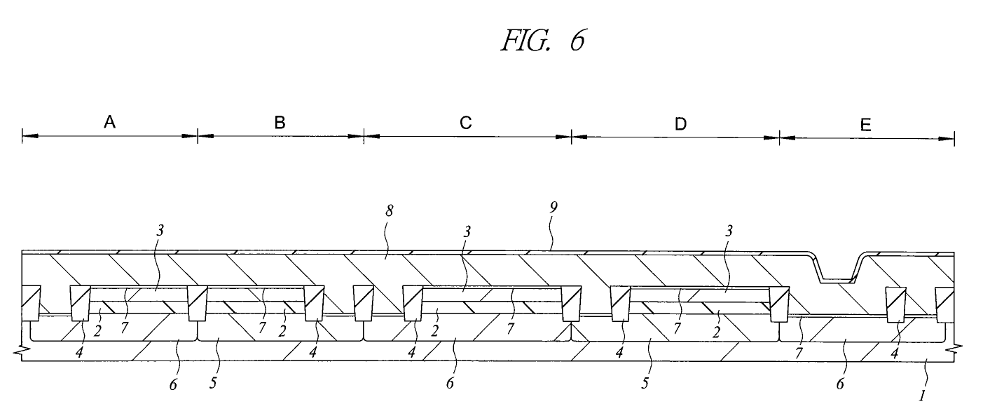

Next, as shown in the FIG. 6, a gate dielectric 7 having a film thickness of approximately 2 nm is formed by thermal oxidation of the surface of the SOI layer 3 in the regions (A) to (D) and the surface of the supporting substrate 1 in the region (E). Then, a polycrystalline silicon film 8 is deposited on the gate dielectric 7 by a CVD method, and a silicon oxide film 9 for gate protection is further deposited on the polycrystalline silicon film 8 by a CVD method.

Next, as shown in FIG. 7, by dry-etching the silicon oxide film 9, the polycrystalline silicon film 8, and the gate dielectric 7, a gate electrode 8A of the NMOS transistor is formed in the region (A), and a gate electrode 8B of the PMOS transistor is formed in the region (B). Also, a gate electrode 8C of the MOS varactor is formed in the region (C), and a gate electrode 8E of the bulk NMOS transistor is formed in the region (E). At this time, in this embodiment, although the polycrystalline silicon film 8 is not left in the region (E), it is also possible to leave it in the region (E) and form a resistor by the left polycrystalline silicon film 8.

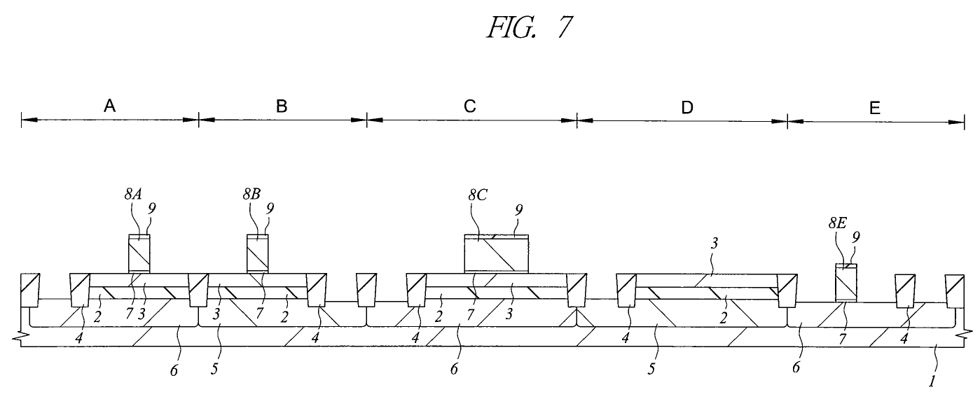

Next, as shown in FIG. 8, n⁻ type semiconductor regions 10, 12, and 13 and a p⁻ type semiconductor region 11 are formed by ion-injecting impurity into the SOI layer 3 located on both sides of each of the gate electrodes 8A to 8C and into the supporting substrate 1 (p type well 6) located on both sides of the gate electrode 8E.

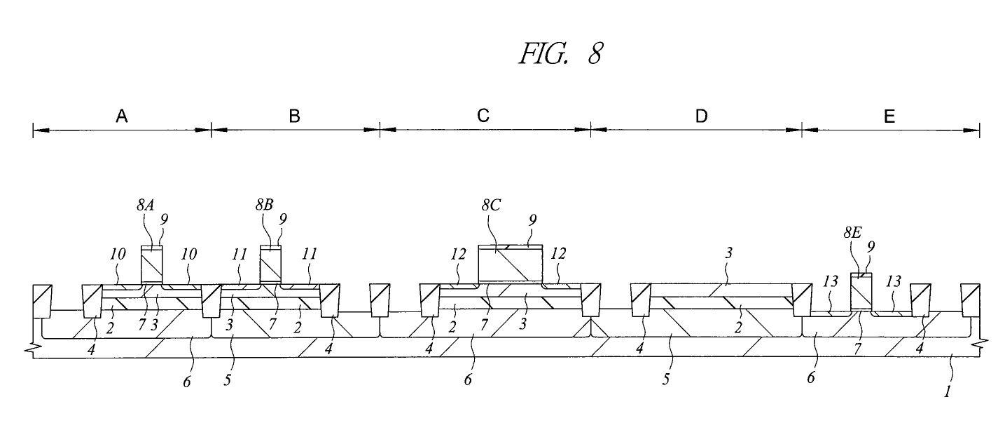

Next, as shown in FIG. 9, sidewall spacers 14 are formed on respective side walls of the gate electrodes 8A, 8B, 8C and 8E by dry-etching an oxide silicon film deposited using a CVD method. Next, a silicon epitaxial layer 21 is grown on each surface of the n⁻ type semiconductor regions 10, 12, the 13 and the p⁻ type semiconductor region 11. Simultaneously, a silicon epitaxial layer 21 is grown on the surface of the supporting substrate 1 located in a region contacting with the wells (n type well 5 and p type well 6).

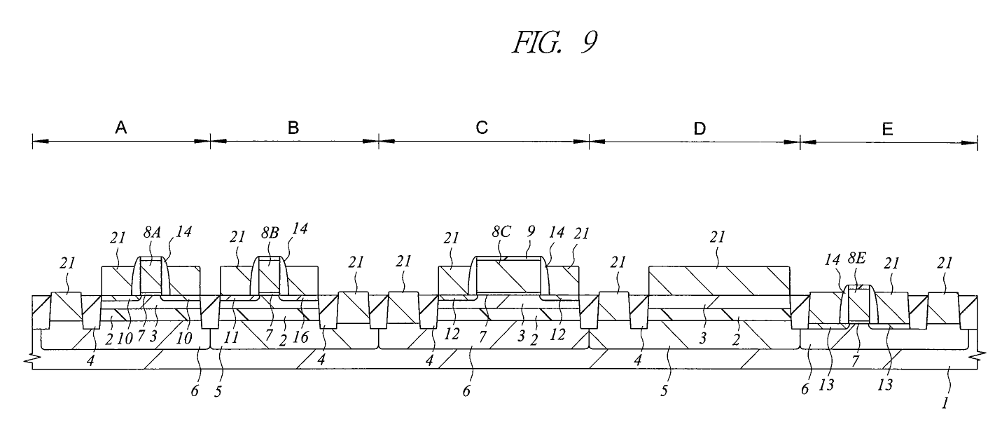

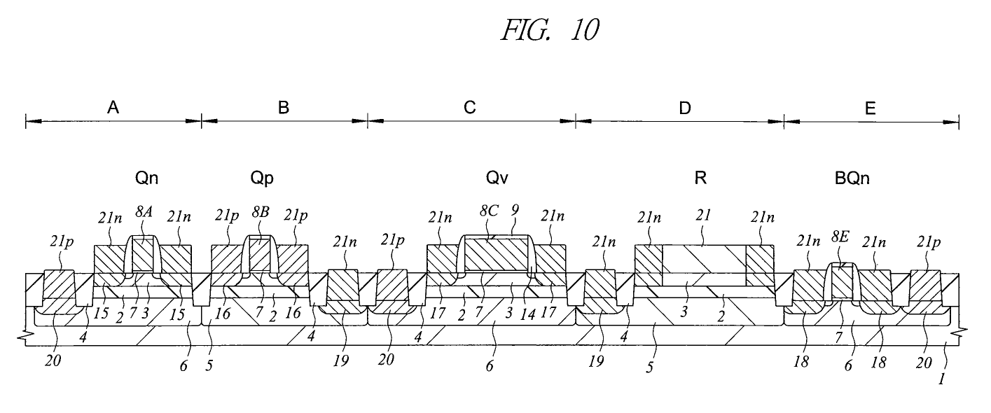

Next, as shown in FIG. 10, impurity is ion-implanted into the gate electrodes 8A to 8C and 8E and the silicon epitaxial layer 21. This ion implantation is carried out using such energy that the impurity implanted into the silicon epitaxial layer 21 reaches the lower SOI layer 3 or well. Also, the silicon epitaxial layer 21 in the region (C) is covered with a photoresist film within the region excluding an electrode forming region, and impurity is ion-implanted only into the electrode forming region

By doing so, in the region (A), an n⁺ type semiconductor region 15 configuring a source and a drain of the NMOS transistor is formed, and an n type epitaxial layer 21n is formed on the n⁺ type semiconductor region 15. A p⁺ type semiconductor region 20 to be a substrate electrode is formed at a part of the p type well 6 in the region (A), and a p type epitaxial layer 21p is formed on the p⁺ type semiconductor region 20.

In the region (B), a p⁺ type semiconductor region 16 configuring a source and a drain of the PMOS transistor is formed, and a p type epitaxial layer 21p is formed on the p⁺ type semiconductor region 16. Also, an n⁺ type semiconductor region 19 to be a substrate electrode is formed at a part of the n type well 5 in the region (B), and an n type epitaxial layer 21n is formed on the n⁺ type semiconductor region 19.

In the region (C), an n⁺ type semiconductor region 17 configuring a source and a drain of the MOS varactor is formed, and an n type epitaxial layer 21n is formed on the n⁺ type semiconductor region 17. Also, a p⁺ type semiconductor region 20 to be a substrate electrode is formed at a part of the p type well 6 in the region (C), and a p type epitaxial layer 21p is formed on the p⁺ type semiconductor region 20.

A pair of n type epitaxial layers 21n to be electrodes of the resistor is formed at a part of the silicon epitaxial layer 21 in the region (D). Also, an n⁺ type semiconductor region 19 to be a substrate electrode is formed at a part of the n type well 5 in the region (D), and an n type epitaxial layer 21n is formed on the n⁺ type semiconductor region 19.

In the region (E), an n⁺ type semiconductor region 18 configuring a source and a drain of the bulk NMOS transistor is formed, and an n type epitaxial layer 21n is formed on the n⁺ type semiconductor region 18. Also, a p⁺ type semiconductor region 20 to be a substrate electrode is formed at a part of the p type well 6 in the region (E), and a p type epitaxial layer 21p is formed on the p⁺ type semiconductor region 20.

Although not shown in the Figures, a silicide layer is then formed on surfaces of the n type epitaxial layer 21n and the p type epitaxial layer 21p using a well-known silicide technique. The silicide layer is made of nickel silicide, Co silicide, or the like.

By steps described so far, an SOI type NMOS transistor Qn is formed in the region (A), and an SOI type PMOS transistor Qp is formed in the region (B). Also, an SOI type MOS varactor Qv is formed in the region (C), and an SOI type resistor R is formed in the region (D). Furthermore, a bulk NMOS transistor BQn is formed in the region (E).

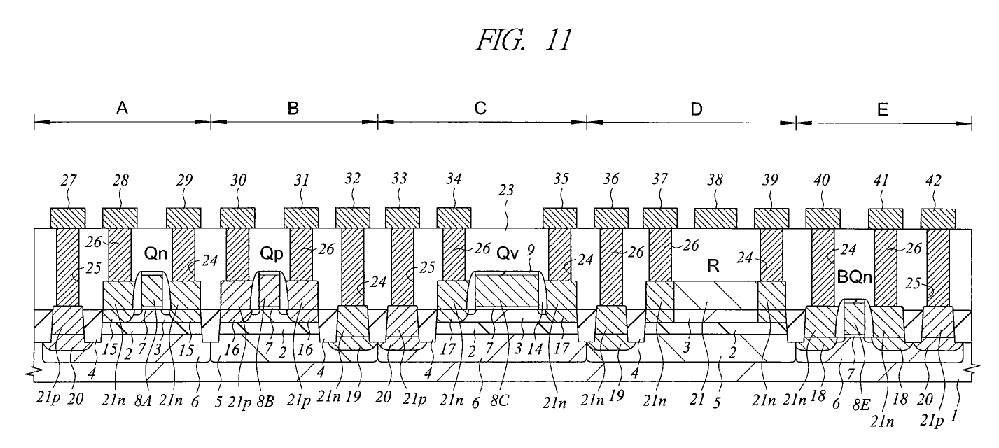

Next, as shown in FIG. 11, an interlayer dielectric 23 formed of an oxide silicon film is deposited using a CVD method. Thereafter, a contact hole 24 that exposes a surface of the n type epitaxial layer 21n and a contact hole 25 that exposes a surface of the p type epitaxial layer 21p are formed by dry-etching the interlayer dielectric 23.

Then, plugs 26 formed of a W film and the like are formed inside the contact holes 24 and 25, and then first layer wirings 27 to 42 formed of an Al alloy film and the like are formed on the interlayer dielectric 23. The first layer wiring 38 that covers the resistor R in the region (D) serves as a shielding layer that prevents fluctuation of resistance values caused by an external induction field etc. Since a subsequent process of forming wirings is the same as that in the well-known technique, its illustration and description will be omitted.

In the present embodiment, although the resistor R is formed using the silicon epitaxial layer 21, it may be formed using a polycrystalline silicon film which is a material of the gate electrodes 8A to 8C and 8E. The resistor in this case has the same structure as that of the MOS varactor that has a gate electrode, but this gate electrode is opened without contacting with any wiring layers.

In the present embodiment, although the gate electrodes 8A to 8C and 8E are formed of the polycrystalline silicon film, they may be so-called fully silicided gate electrodes by making the polycrystalline silicon films fully silicided. Alternatively, the gate electrode may be formed by a metal material such as a TiN film. That is, a passive element can be simultaneously formed using a process of forming the MOS transistor for logic circuit.

Thus, as described above, according to the present embodiment, the MOS varactor and the resistor can be formed using the same number of masks and manufacturing steps as those used in the process of forming the MOS transistor for logic circuit. At this time, like the manufacturing process for the CMOS transistor, desirable characteristics can be obtained by changing, to desirable polarity, each of a conductivity type of a portion corresponding to a channel and those of portions corresponding to a source and a drain. Next, the characteristic of the passive element formed thus far will be detailed in the following embodiment.

### Embodiment 2

In the present embodiment, electrical characteristics of the MOS varactor Qv manufactured according to Embodiment 1 will be described. This MOS varactor is configured as an N channel inversion type of a combination shown in above Table 1. That is, the p type well 6 is doped with p type impurity (boron) of order of 10¹⁷/cm³ while the impurity concentration of the SOI layer 3 is suppressed by order of 10¹⁶/cm³. The n⁺ type semiconductor region (source and drain) 17 is doped with n type impurity (for example, arsenic) of approximately 10²⁰/cm³, and the portion (p⁺ type semiconductor region 20) contacting with the supporting substrate 1 (p type well 6) is doped with p type impurity (boron) of approximately 10²⁰/cm³. The thickness of the gate dielectric 7 is 2 nm, and that of the BOX layer 2 is 10 nm. Also, the film thickness of the SOI layer 3 after formation of the device is 15 nm.

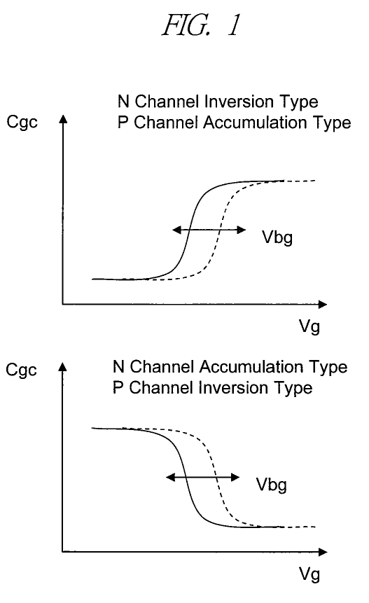

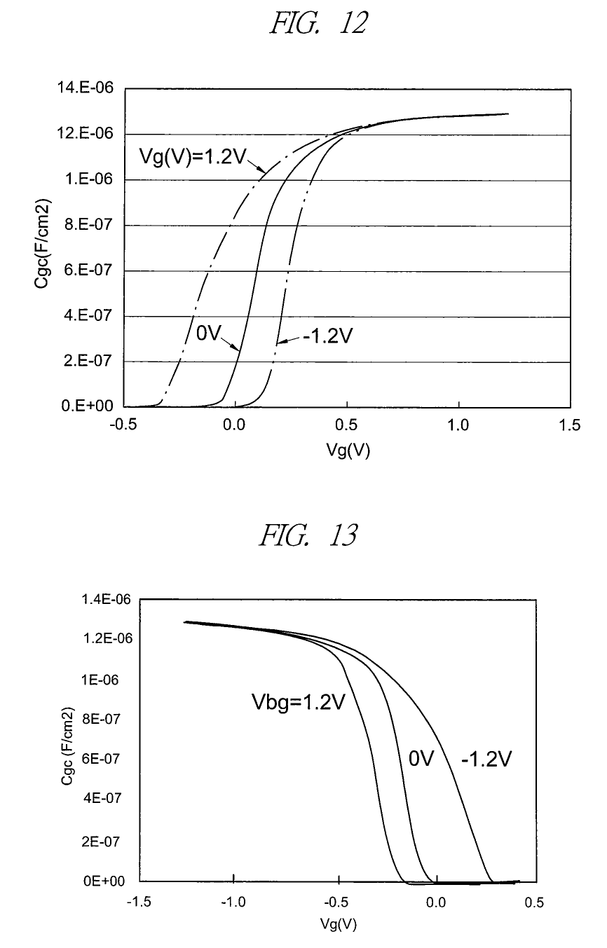

The capacitance characteristic of the MOS varactor Qv formed under the above condition is shown in FIG. 12. This characteristic is the n channel inversion type shown in FIG. 1. A horizontal axis in the Figure is values of voltage Vg of the front gate, and a vertical axis is values of capacitance in terms of an area. Although three curves are shown in the Figure, they correspond to respective cases where back bias voltages are 1.2 V, 0 V and −1.2 V.

When the back bias is applied in the negative direction, as the capacitance rises, the gate voltage is higher, which results in the curve becoming steeper. In contrast, when the back bias is applied in the positive direction, as the front gate voltage is lower, the capacitance rises, which results in the rising curve becoming looser. Even when either back bias voltage is applied in the positive or negative direction, a change in the capacitance shows a smooth curve, thereby allowing the characteristic to be easily used as the variable capacitance.

Since the MOS varactor Qv is formed by the CMOS manufacturing process, the MOS varactor having opposite polarity can be formed simultaneously. For example, an n type well is formed by doping n type impurity (e.g., phosphorous) having the same concentration as that of the above (order of 10¹⁷/cm³), a source and a drain are formed by doping boron having the same concentration as that of the above (approximately 10²⁰/cm³) in the SOI layer 3 located on the n type well, and a n⁺ type semiconductor region is formed by doping phosphorous having the same concentration as that of the above (approximately 10²⁰/cm³) in the portion contacting with the supporting substrate 1. By doing so, the characteristic of the P channel inversion type as shown in FIG. 13 was obtained. This is a characteristic in which positive and negative polarities shown in FIG. 12 are completely inversed.

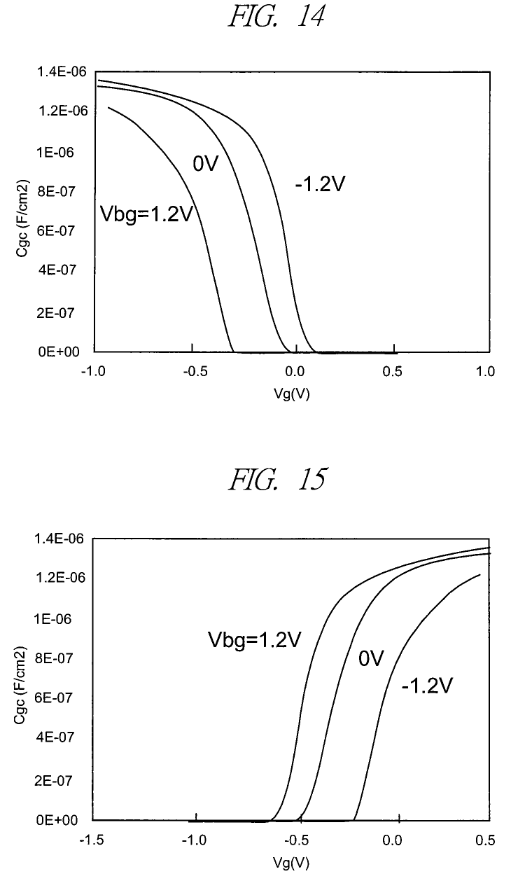

Also, a p type well is formed by doping boron having the same concentration as that of the above, a source and a drain are formed by doping phosphorous having the same concentration as that of the above in the SOI layer 3 located on the p type well, and the portion contacting with the supporting substrate 1 is doped with phosphorous having the same concentration as that of the above. By doing so, the characteristic of the P channel accumulation type as shown in FIG. 14 was obtained.

Further, an n type well is formed by doping phosphorous having the same concentration as that of the above, a source and a drain are formed by doping phosphorous having the same concentration as that of the above in the SOI layer 3 located on the n type well, and the portion contacting with the supporting substrate 1 is doped with phosphorous having the same concentration as that of the above. By doing so, the characteristic of the N channel accumulation type as shown in FIG. 15 was obtained.

Also, even in either case, when the back bias voltage is applied in the positive direction (this corresponds to a case of Vbg=1.2 V for the n channel and Vbg=−1.2 V for the p channel), a depletion layer spreads in the supporting substrate 1 located on the back surface of the BOX layer 2. Therefore, compared to a case where the back bias is applied from 0 to the negative direction or where back bias similar to that applied from 0 to the negative direction is applied to the bulk type MOS varactor formed with the same impurity concentration, the parasitic capacitance was reduced to one third to one fifth.

### Embodiment 3

In the present embodiment, there will be described a device layout in the case where the MOS varactor Qv formed in above Embodiment 1 is a differential type, and described a voltage controlled oscillation circuit using this differential type MOS varactor Qv.

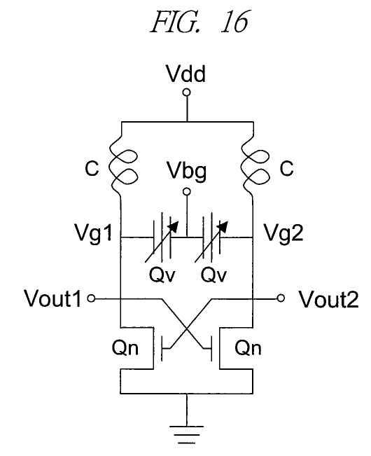

First, FIG. 16 shows a voltage controlled oscillation circuit (VCO) in which the type MOS varactor Qv is a differential type. This voltage controlled oscillation circuit comprises two NMOS transistors Qn, two MOS varactors Qv, and two inductors (C). The NMOS transistors Qn and the MOS varactors Qv are ones formed in above Embodiment 1. A condition of manufacturing the device is the same as that of above Embodiment 2. In order to operate the FDSOI device under this condition, power voltage Vdd is set at 1.2 V. At this voltage, the NMOS transistors Qn and the MOS varactors Qv were successfully operated without any problems.

In the voltage controlled oscillation circuit shown in FIG. 16, two NMOS transistors Qn and two MOS varactors Qv form pairs, respectively. Particularly, in order to perform a differential operation of the paired two MOS varactors Qv, if the gate electrodes therein are arranged alternately as a finger shape, the Q value is further higher, whereby the better characteristic is obtained.

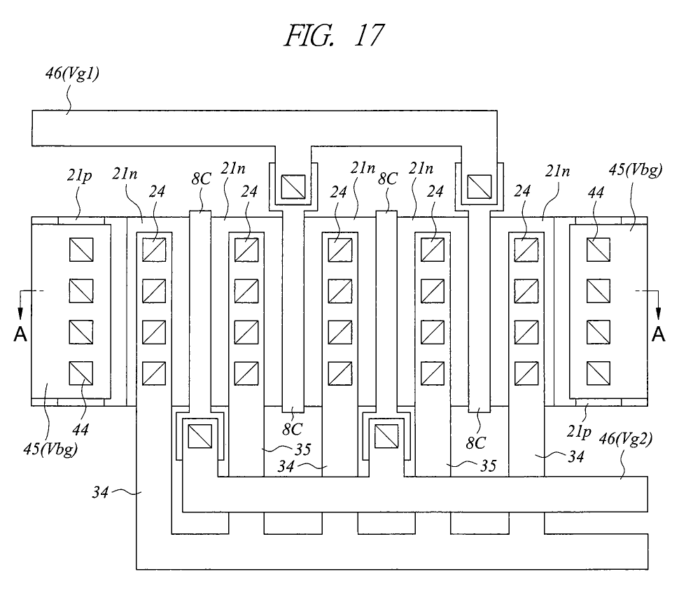

The plane layout of the MOS varactor suitable for the above-mentioned differential operation is shown in FIG. 17. A cross-sectional structure taken along A-A line of FIG. 17 is shown by FIG. 18. In the Figure, the reference numeral “43” denotes a second-layer interlayer dielectric; “45” a second layer wiring for supplying back bias voltage; and “46” a second layer wiring for supplying the gate electrode Vg.

Active regions of the MOS varactor are horizontally aligned, and the p⁺ type semiconductor regions 20 for applying the back bias voltage Vbg are formed at both ends of an entirety of the aligned active regions. In the active regions, two types of gate fingers are arranged (in this Figure, a total of four gate fingers are arranged alternately). Each of regions sandwiched by the fingers is a portion corresponding to a source and drain of the transistor, and the n⁺ type semiconductor region 17 is formed at each of the sandwiched regions. In the SOI type MOS varactor according to the present invention, the n⁺ type semiconductor regions 17 are usually connected to a power source of fixed voltage, and a voltage of 0 V is applied in the present embodiment. Control voltage of the VCO is applied to the two back bias terminals (p⁺ type semiconductor regions 20).

When the back bias voltage Vbg is 0 V, the operating characteristic of the circuit according to the present embodiment is substantially the same as that of the ordinary bulk type circuit. An existing circuit can be replaced without any change. Further, when a circuit constant is adjusted to make the back bias Vbg applied in the positive direction (+0.5 V as a center value), the parasitic resistance of the varactor is reduced to approximately one third. As a result, a frequency-adjustment range of the VCO can be enlarged by approximately 20%. Furthermore, when the back bias voltage Vbg is varied in a range from +0.2 v to +1.2 v in the positive direction, the frequency-adjustment range is further enlarged. Compared to the VCO having the same structure using the conventional type of varactor, the frequency-adjustment range is improved by 60%.

### Embodiment 4

In the present embodiment, an electrical characteristic of the resistor R manufactured in above Embodiment 1 will be described. The thickness of the SOI layer 3 and that of the BOX layer 2 are identical to those shown in above Embodiment 2. The impurity concentration and the conductivity type of the well formed in the supporting substrate 1 are also identical to those in above Embodiment 2. In the p⁺ type semiconductor region 16 (source and drain) formed in the portion contacting with the supporting substrate 1, boron having a concentration of approximately 10²⁰/cm³ is doped. In the SOI layer 3 in a portion corresponding to the channel in terms of the MOS transistor, phosphorous having a low concentration (approximately 10¹⁷/cm³) is doped.

The resistor R manufactured in Embodiment 1 has no gate electrode, but shows the same resistance characteristic as that of a case of applying a gate voltage of 0 V to a normally-on type NMOS transistor. Arsenic having the same concentration as that used in Embodiment 2 is doped in portions corresponding to the source and drain of the SOI layer 3. Also, although being shown also in Embodiment 1, the first layer wiring 38 serving as a shielding layer is formed on the resistor R in order to stabilize a channel surface potential. Thickness of the interlayer dielectric 23 that isolates the channel surface and the first layer wiring 38 is 400 nm, and its parasitic capacitance is dramatically smaller than that of a case of providing a gate electrode to ground it in an alternating-current manner.

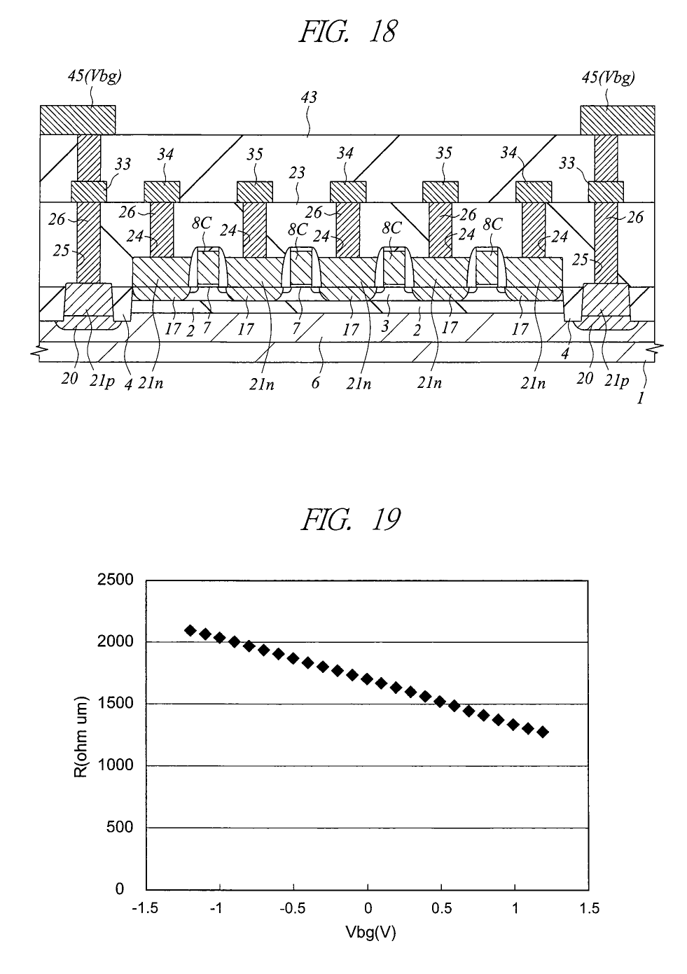

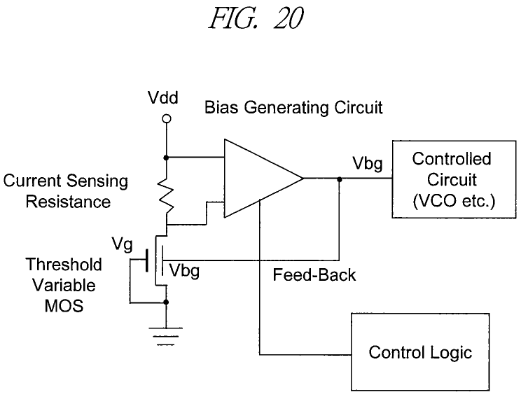

The characteristic of the resistor having a structure as mentioned above is shown in FIG. 19. A horizontal axis in the Figure represents back bias voltage Vbg. This Figure shows a case where a distance between the diffusion layers, which corresponds to gate length in terms of the MOS transistor, is 1 μm, and has a resistance value (Ωμm) normalized by channel width.

As shown in the Figure, when the back bias voltage was changed from −1.2 V to 1.2 V, the resistance value was linearly changed by approximately 30%. As long as the back bias voltage is within breakdown voltage of an oxide silicon film configuring the BOX layer 2, the back bias voltage can be further raised, whereby a change of the resistance can be varied by several times of 30%.

Since the resistor R is formed by a CMOS manufacturing process, a resistor having opposite polarity can be formed simultaneously. For example, a p type well is formed by doping boron having the same concentration as that of the above, a source and a drain are formed by doping boron having the same concentration as that of the above in the SOI layer 3 located on the p type well, and the portion contacting with the supporting substrate 1 is doped with phosphorous having the same concentration as that of the above, whereby the resistor is formed. By doing so, the resistor having the same resistance change characteristic as that in FIG. 19 was obtained. However, since p type silicon has lower mobility than n type silicon, the resistance value was twice more than that of the case of FIG. 19 when the resistor was formed with the same impurity concentration.

Further, also in either case, when the back bias voltage is applied in the positive direction (this corresponds to a case where Vbg for an n channel is positive and a case where Vbg for a p channel is negative), a depletion layer spreads in the supporting substrate 1 located on the back surface of the BOX layer 2. Therefore, compared to a case where the back bias is applied from 0 to the negative direction or a case of the bulk type resistor formed by a configuration having the same impurity concentration (in this case, a substrate bias is not usually applied), the parasitic capacitance was reduced to approximately one third to one fifth.

### Embodiment 5

In the present embodiment, a method of controlling operating characteristics of a circuit comprising a back-bias dependent MOS varactor as shown in Embodiment 2 or a back-bias dependent resistor as shown in Embodiment 1 will be described by using a control logic assembled in the same chip.

FIG. 20 shows an example of the circuit. In this circuit, a threshold variable MOS (zero gate bias in this embodiment) and a current sensing resistance are disposed, wherein the characteristics of the MOS transistor, the varactor, and the variable resistance that are varied per chip or per region in the chip feeds back, to a back bias terminal of the threshold variable MOS via the bias generating circuit, output voltage from the current sensing resistance. A relation between back bias dependence of the varactor or variable resistor and that of the threshold variable MOS is corrected in advance.

In order to set, at predetermined values, characteristics of a controlled circuit such as VCO and an operation mode of the circuit (for example, oscillation frequency), a necessary output from a control logic circuit is inputted to the bias generating circuit. By doing so, the passive element such as a varactor in the controlled circuit is feed-back controlled to obtain desired characteristics. By providing this control system, the characteristic of the controlled circuit can be arbitrarily controlled, and variations in the characteristics among the chips or in the chip can be suppressed.

In fact, when a process in which variation of threshold voltage of the MOS transistor for logic circuit has standard deviation of 30 mV was adopted, all the chips were kept within the standards if a feedback control circuit mentioned above is provided or even if no feedback control circuit mentioned above is provided and a circuit of such design that approximately 20% of all the chips is outside the standards is manufactured.

As described above, the present invention made by the inventors has been described based on the embodiments. However, needless to say, the present invention is not limited to those embodiments, and may be variously modified and altered within a scope of not departing from the gist of the present invention.

The present invention can be applied to a semiconductor device comprising a varactor or resistor used in a wireless information communication apparatus.

What is claimed is:

1. A semiconductor device comprising:
an SOI substrate including a supporting substrate made of monocrystalline silicon, an insulating layer formed over the supporting substrate, and a SOI layer formed over the insulating layer and made of monocrystalline silicon; and
a varactor formed over a first region in a main surface of the SOI substrate,
wherein the varactor comprises a first gate electrode formed over the SOI layer via a first gate dielectric, and a first diffusion layer formed in the SOI layer located on both sides of the first gate electrode, and
capacitance formed by the SOI layer, the first gate dielectric, and the first gate electrode is varied by applying bias voltage to the supporting substrate located under the first gate electrode.

2. The semiconductor device according to claim 1,
wherein the bias voltage is applied in a positive direction.

3. The semiconductor device according to claim 1,
wherein the varactor is operated as a capacitance device when an inversion layer is formed in the SOI layer.

4. The semiconductor device according to claim 1,
wherein the varactor is operated as a capacitance device when an accumulation layer is formed in the SOI layer.

5. The semiconductor device according to claim 1,
wherein a second region in the main surface of the SOI substrate includes a second gate electrode formed over the SOI layer via a second gate dielectric, and a second diffusion layer formed in the SOI layer located on both sides of the second gate electrode, and
a fully-depleted MOS transistor is formed in the second region so that threshold voltage is varied by applying the bias voltage to the supporting substrate located under the second gate electrode.

6. The semiconductor device according to claim 1,
wherein the bias voltage applied to the supporting substrate is optimized by a control circuit formed over the SOI substrate.

7. The semiconductor device according to claim 1,
wherein the varactor comprises a first varactor and a second varactor, each of which has a plurality of first gate electrodes, and,
the plurality of first gate electrodes of the first varactor and that of the second varactor are arranged mutually alternately.

8. A semiconductor device comprising:
an SOI substrate including a supporting substrate made of monocrystalline silicon, an insulating layer formed over the supporting substrate, and an SOI layer formed over the insulating layer and made of monocrystalline silicon; and
a resistor formed over a first region in a main surface of the SOI substrate,
wherein the resistor comprises a first conductive layer formed over the SOI layer via a first insulating layer, and a first diffusion layer formed in the SOI layer located on both sides of the first conductive layer; and,
electrical resistance of the SOI layer located under the first conductive layer is varied by applying bias voltage to the supporting substrate located under the first conductive layer.

9. The semiconductor device according to claim 8,
wherein the bias voltage is applied in a positive direction.

10. The semiconductor device according to claim 8,
wherein a first layer wiring disposed so as to cover the first conductive layer is formed over the first conductive layer; and,
a fixed potential of the resistor is supplied via the first layer wiring.

11. The semiconductor device according to claim 8,
wherein a second region in the main surface of the SOI substrate includes a second gate electrode formed over the SOI layer via a second gate dielectric, and a second diffusion layer formed in the SOI layer located on both sides of the second gate electrode,
a fully-depleted MOS transistor is formed in the second region so that threshold voltage is varied by applying the bias voltage to the supporting substrate located under the second gate electrode.

12. The semiconductor device according to claim 11,
wherein the first conductive layer is composed of a floating first gate electrode.
